(19) United States
(12) Patent Application Publication
(10) Pub. No.: US 2009/0255803 A1
(43) Pub. Date: Oct. 15, 2009

(54) PLASMA GENERATING APPARATUS, DEPOSITION APPARATUS, AND DEPOSITION METHOD

(75) Inventors: Hitoshi NAKAGAWARA, Tachikawa-shi (JP); Masao SASAKI, Hachioji-shi (JP); Takayuki MORIWAKI, Hino-shi (JP); Tomoyasu SAITO, Tachikawa-shi (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/423,051

(22) Filed: Apr. 14, 2009

(30) Foreign Application Priority Data
Apr. 15, 2008 (JP) 2008-105692

(51) Int. Cl. C23C 14/35

(52) U.S. Cl. 204/192.15; 204/298.16; 204/192.12

(57) ABSTRACT

A plasma generating apparatus emits a plasma beam from a plasma gun and thereafter deforms the emitted plasma beam by a pair of opposing first magnets arranged to sandwich the plasma beam. The plasma generating apparatus includes at least one second magnet which is arranged between the plasma gun and the first magnets, includes a hole through which the plasma beam passes and a magnet portion of it extending outside from the hole in a direction perpendicular to the plasma beam, and forms a magnetic field having magnetic lines reaching outside from the hole or reaching the hole from outside. At least one second magnet concentrates the emitted plasma beam.

### BACKGROUND OF THE INVENTION

1. Field of the Invention

The present invention relates to a plasma generating apparatus, a deposition apparatus which uses the plasma generating apparatus, and a deposition method which uses the deposition apparatus.

2. Description of the Related Art

In recent years, mass production of a display device such as a liquid crystal display (LCD) or a plasma display panel (PDP) which uses a large display substrate is strongly sought.

In formation of a thin film such as a transparent conductive ITO film for a large display substrate such as a LCD or PDP, or an MgO film as an electrode protection film on a front panel, for higher production and higher resolution of the display, an ion plating method attracts attention as a deposition method that replaces the electron beam deposition method or sputtering method.

This is because the ion plating method has various advantages such as a high deposition rate, formation of a high-density film, and a large process margin, and that it enables deposition on a large substrate by controlling a plasma beam by a magnetic field. In the ion plating method, a hollow cathode type ion plating method is particularly expected for deposition on a large display substrate.

Regarding the hollow cathode type ion plating method, Japanese Patent Laid-Open No. 9-78230 discloses use of a pressure gradient type plasma gun (UR-type plasma gun) as a plasma generating mechanism.

The UR-type plasma gun comprises a hollow cathode and a plurality of electrodes. The plasma gun receives Ar gas to generate high-density plasma. A plurality of different magnetic fields change the shape and orbit of the plasma beam and guide the plasma beam to a deposition chamber. The plasma beam generated by the plasma gun passes between opposing permanent magnets which sandwich the plasma beam. Thus, the plasma beam deforms into, for example, a flat spreading plasma beam.

Japanese Patent Laid-Open No. 9-78230 also discloses a technique for irradiating a volatile material on a volatile material tray with the flat spreading plasma beam over a wide range.

According to Japanese Patent Laid-Open No. 9-78230, as the plasma beam irradiates the volatile material, for example, MgO, on the volatile material tray over the wide range, the evaporation source can be formed wide, so that a film can be deposited on a wide substrate.

With the conventional deposition apparatus disclosed in Japanese Patent Laid-Open No. 9-78230, however, a sufficient deposition rate cannot be obtained.

When a higher deposition rate is needed, higher power is supplied to the plasma gun which generates the plasma beam, and higher energy density of the plasma beam entering the surface of MgO on the volatile material tray is obtained.

If, however, the power to be supplied to the plasma gun is excessively high, the consumable components in the plasma gun are consumed quickly. Then, the maintenance period of the plasma gun shortens, adversely affecting the productivity. For this reason, higher power cannot be supplied at the risk of shortening the maintenance period of the plasma gun. Therefore, it is difficult to increase the deposition rate.

The electrons in the plasma beam can have higher energy by higher discharge impedance of the plasma beam to be generated, and the deposition rate may be increased accordingly. To increase the discharge impedance, for example, the pressure during film formation must be reduced, or the flow rate of Ar gas to be introduced into the plasma gun must be reduced.

As the flow rate of gas during film formation largely influences the state of the plasma, the gas must always be introduced stably. In view of excluding any unstable process condition as well, the scheme of lowering the flow rate of Ar gas cannot be employed in the production.

### SUMMARY OF THE INVENTION

It is an object of the present invention to provide a plasma generating apparatus, deposition apparatus, and deposition method which can raise the deposition rate without increasing the power to be supplied to the plasma gun, reducing the pressure during film formation, or lowering the flow rate of Ar gas to be introduced into the plasma gun.

According to the present invention, there is provided a plasma generating apparatus which emits a plasma beam from a plasma gun and thereafter deforms the emitted plasma beam by a pair of opposing first magnets arranged to sandwich the plasma beam, the apparatus comprising at least one second magnet which is arranged between the plasma gun and the first magnets, includes a hole through which the emitted plasma beam passes and a magnet portion of one second magnet extending outside from the hole in a direction perpendicular to the emitted plasma beam, and forms a magnetic field including magnetic lines reaching outside from the hole or reaching the hole from outside, wherein the at least one second magnet concentrates the emitted plasma beam.

The present invention can provide a plasma generating apparatus, deposition apparatus, and deposition method which can raise the deposition rate without increasing the power to be supplied to the plasma gun, reducing the pressure during film formation, or lowering the flow rate of Ar gas to be introduced into the plasma gun.

Further features of the present invention will become apparent from the following description of exemplary embodiments with reference to the attached drawings.

### BRIEF DESCRIPTION OF THE DRAWINGS

FIG. 1 is a side view for explaining a plasma generating apparatus according to the present invention and an example of a deposition apparatus which utilizes it;

FIG. 2 is a plan view for explaining the plasma generating apparatus according to the present invention and the example of the deposition apparatus which utilizes it;

FIG. 3 is a perspective view for explaining the plasma generating apparatus according to the present invention and the example of the deposition apparatus which utilizes it; and

FIGS. 4A, 4B, and 4C are views showing examples of the second magnet of the present invention.

### DESCRIPTION OF THE EMBODIMENTS

An embodiment of the present invention will be described hereinafter with reference to the accompanying drawings.

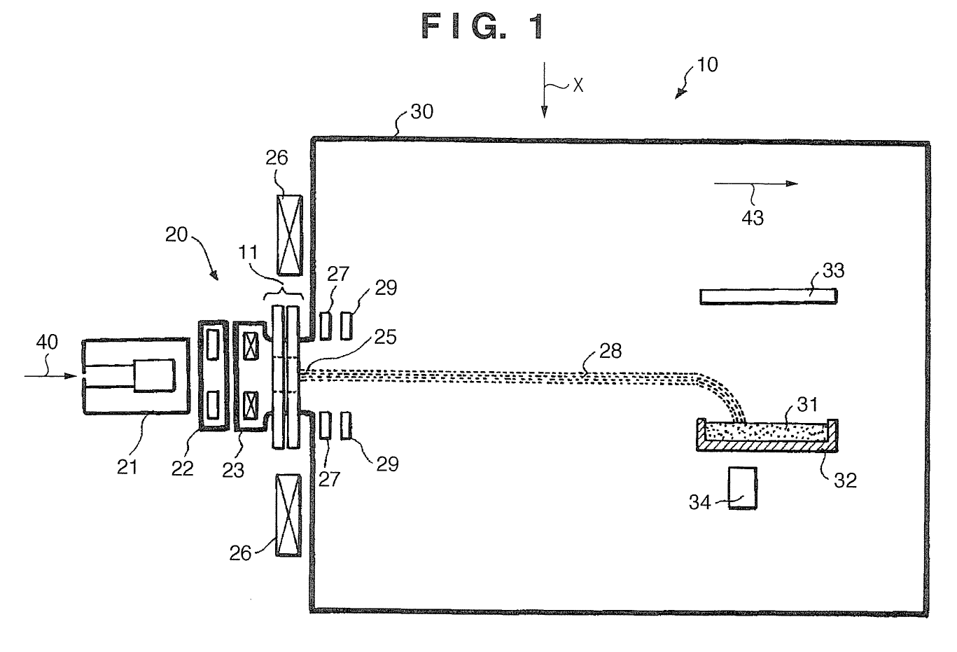

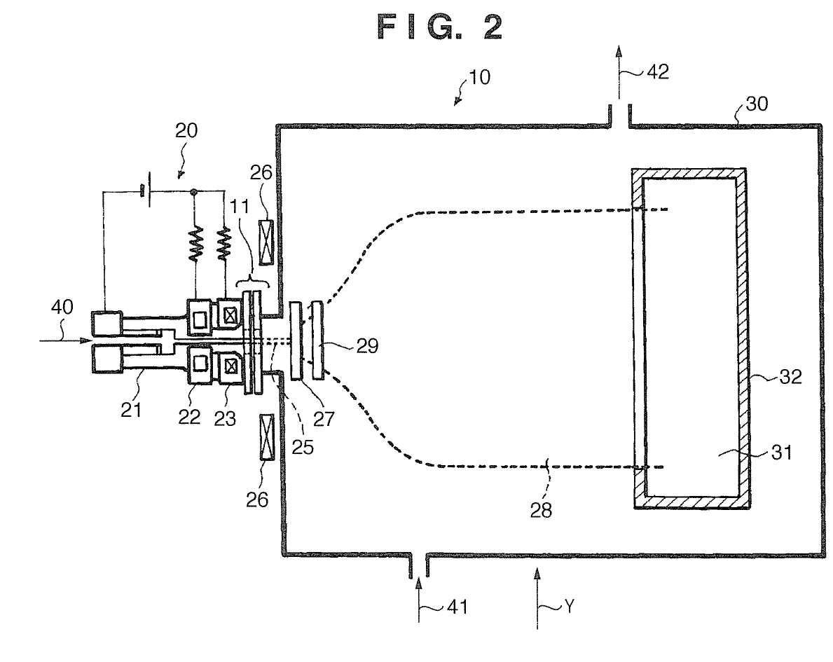

FIG. 1 is a side view of an example of a deposition apparatus 10 employed in a deposition method of the present invention. FIG. 2 is a plan view of the deposition apparatus 10 shown in FIG. 1. FIG. 2 shows a state seen from the direction of an arrow X in FIG. 1, and FIG. 1 shows a state seen from the direction of an arrow Y in FIG. 2.

A tray 32 accommodating a volatile material 31 is disposed at the lower portion in a deposition chamber 30 of the deposition apparatus 10. The deposition chamber 30 can be evacuated to a vacuum. A substrate 33 (e.g., a large glass substrate for a display) to undergo deposition is arranged at the upper portion in the deposition chamber 30 to oppose the volatile material tray 32. When forming a film on the substrate 33 continuously using the volatile material 31, the substrate 33 is continuously transported as indicated by an arrow 43 at a predetermined distance from the tray 32 while being held by a substrate holder (not shown).

In the embodiment shown in FIGS. 1 and 2, a plasma gun 20 arranged outside the deposition chamber 30 has a hollow cathode 21, electrode magnet 22, and electrode coil 23, and is arranged to be coaxial with them along an almost horizontal axis.

A coreless coil 26 to draw it into the deposition chamber 30 is set downstream (a direction along which the plasma beam travels) of the electrode coil 23.

First magnets 27 and 29 formed of a pair of opposing permanent magnets which sandwich the plasma beam 25 are disposed downstream of the coil 26. The plasma beam 25 passes through the magnetic fields formed by the first magnets 27 and 29. While passing, the plasma beam 25 forms a flat plasma beam 28. The first magnets include a pair of magnets or a plurality of pairs of magnets.

Although the first magnets 27 and 29 are arranged in the deposition chamber 30 in the example shown in FIGS. 1 and 2, they may be arranged outside the deposition chamber 30.

In the deposition apparatus 10 of the present invention, before the plasma beam 25 emitted by the plasma gun 20 toward the deposition chamber 30 and passing through the electrode coil 23 passes between the first magnets 27 and 29 which render the plasma beam 25 flat, the plasma beam 25 passes through a hole 12 of at least one second magnet 11 arranged between the plasma gun 20 and the first magnets 27 and 29, so that it concentrates.

The second magnet is a magnet which has a hole 12 through which the plasma beam 25 passes, and a magnet portion of it extending outside from the hole 12 in a direction perpendicular to the plasma beam 25, and generates magnetic lines reaching outside from the hole 12 or reaching the hole 12 from outside. As the second magnet 11, an annular permanent magnet can be used. The second magnet 11 concentrates the plasma beam 25 in its hole 12 without interfering with the travel of the plasma beam 25 passing through the hole 12. Hence, the second magnet 11 may comprise one annular magnet or a plurality of magnets.

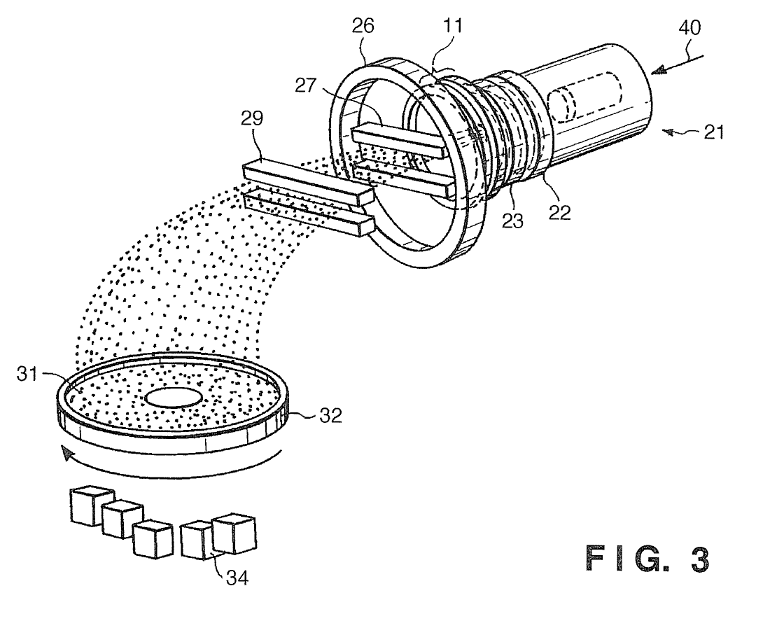

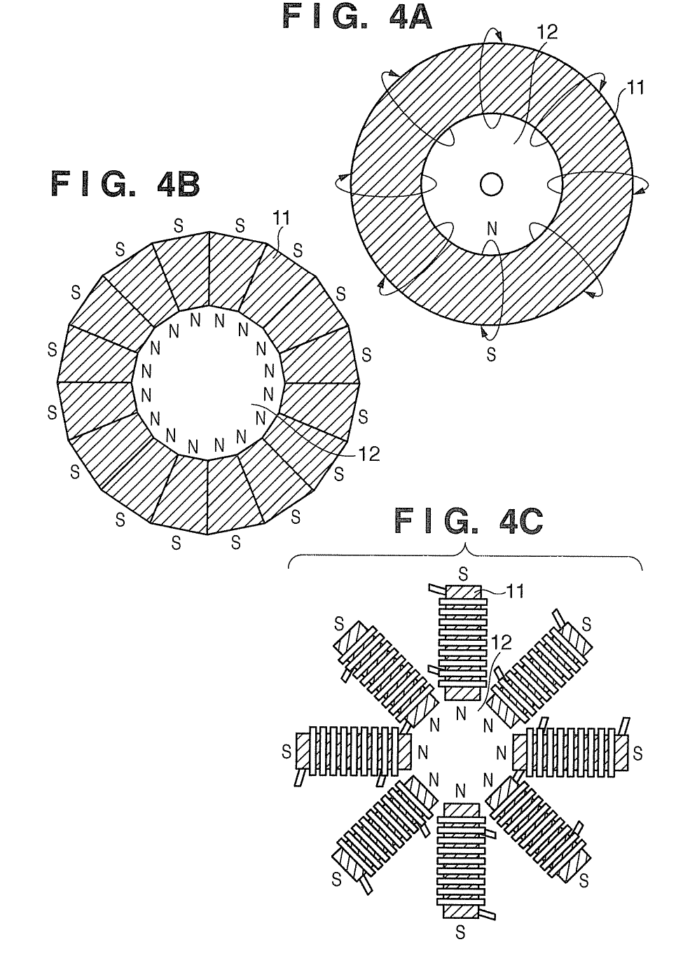

Therefore, for example, the second magnet 11 having a uniform predetermined magnetic flux density can be obtained by using an annular conductive member having the hole 12 through which the plasma beam 25 passes, as shown in FIGS. 3 and 4A. At this time, the second magnet 11 has magnetic poles such that the inner side of the annular conductive member forms an N pole and the outer side thereof forms an S pole, or vice versa. Either magnetic pole structure can be selected in accordance with the polarities of the electrode magnet 22 and electrode coil 23.

With this structure, the plasma beam 25 passing through the hole 12 is concentrated.

When the heat of the plasma beam 25 or the like raises the temperature, the magnetic characteristics of the second magnet 11 may be adversely affected. To prevent this, a coolant such as water flows through a support for the second magnet 11.

When the second magnet 11 as described above is arranged between the plasma gun 20 and the first magnets 27 and 29, the magnetic field formed by the second magnet 11 may be able to eventually increase the discharge impedance of the plasma beam 25.

As the second magnet 11, in place of arranging one annular magnet as shown in FIG. 4A, a plurality of permanent magnets may be arranged point-symmetrically about the plasma beam 25 as the center, as shown in FIG. 4B. In this case, the plurality of permanent magnets which are arranged annularly may be fixed to a conductive member made of copper or the like, and a hole may be formed in the conductive member.

As the second magnet 11, a plurality of electromagnets may be arranged point-symmetrically about the plasma beam 25 as the center, as shown in FIG. 4C. In this case, the plurality of electromagnets which are arranged annularly may be fixed to a conductive member made of copper or the like, and a hole may be formed in the conductive member.

The conductive member which supports the plurality of permanent magnets or electromagnets may have a channel through which a coolant such as water flows.

### Example 1

An example of a film deposition method will be described concerning a case in which magnesium oxide (MgO) is to be deposited using the deposition apparatus 10 shown in FIGS. 1 and 2.

When forming a film on the substrate 33, the volatile material 31 is put in the tray 32. The substrate holder (not shown) holds the substrate 33 which is to undergo deposition. The interior of the deposition chamber 30 is evacuated as indicated by an arrow 42 and set at a predetermined vacuum degree. Simultaneously, oxygen is supplied as a reaction gas into the deposition chamber 30, as indicated by an arrow 41.

In this state, Ar gas is introduced as a plasma gas into the plasma gun 20, as indicated by an arrow 40. The plasma beam 25 generated by the plasma gun 20 concentrates by the function of the magnetic field formed by the second magnet 11 and is drawn into the deposition chamber 30. The drawn plasma beam 25 passes through magnetic fields formed by the two pairs of first magnets 27 and 29, respectively. While passing through the pairs of first magnets 27 and 29, the plasma beam 25 deforms into the flat plasma beam 28.

The flat plasma beam 28 is deflected by a magnetic field formed by an anode magnet 34 arranged under the volatile material tray 32 and is drawn onto the volatile material 31, and heats the volatile material 31. As a result, the heated part of the volatile material 31 evaporates and reaches the substrate 33 held by the substrate holder (not shown) and moving in the direction of the arrow 43, thus forming a film on the upper surface of the substrate 33.

The deposition conditions are as follows:

| | |
|---|---|
| Volatile Material: | Magnesium Oxide (MgO) |
| Film Thickness: | 12,000 Å |
| Discharge Pressure: | 0.1 Pa |
| Ar Flow Rate: | 11 sccm (0.18 ml/sec) |
| O₂ Flow Rate: | 400 sccm (6.7 ml/sec) |
| Deposition rate: | 175 Å/sec |

As a result, the plasma had a higher discharge impedance while stabilizing the flow rate of Ar gas necessary to maintain the plasma which is an important condition of the deposition process. Therefore, without increasing the power to be supplied to the plasma gun 20, the deposition rate was higher by 30% than that of a case in which the second magnet 11 was not employed.

### Example 2

A simulation was conducted on an integrated magnetic field of the second magnet 11 employed in the vacuum deposition apparatus 10 of the present invention. The result was compared with a case in which the second magnet was not employed.

As a result, the plasma beam 25 passing through the second magnet 11 concentrated to about 60% when compared to the case in which the second magnet was not employed.

The shape and magnetic characteristics of the second magnet 11 (annular permanent magnet) employed for the simulation are as follows:

| | | |
|---|---|---|
| Size | inner diameter: | 60 (mm) |
| | outer diameter: | 80 (mm) |
| | thickness: | 10 (mm) |

| | |
|---|---|
| Coercive Force (H): | 11,750 (Oe) |
| Residual Magnetic Flux Density (Br): | 13,900 (Gauss) |

The deposition method according to the present invention is suitable for deposition on a large substrate as in, for example, the manufacture of a plasma display panel.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-105692, filed Apr. 15, 2008, which is hereby incorporated by reference herein in its entirety.

What is claimed is:

1. A plasma generating apparatus which emits a plasma beam from a plasma gun and thereafter deforms the emitted plasma beam by a pair of opposing first magnets arranged to sandwich the plasma beam, the apparatus comprising
at least one second magnet which is arranged between the plasma gun and the first magnets, includes a hole through which the emitted plasma beam passes and a magnet portion of it extending outside from the hole in a direction perpendicular to the emitted plasma beam, and forms a magnetic field including magnetic lines reaching outside from the hole or reaching the hole from outside,
wherein said at least one second magnet concentrates the emitted plasma beam.

2. The apparatus according to claim 1, wherein said second magnet comprises one of an annular permanent magnet and an annular electromagnet which is formed such that the same magnetic poles are present in the hole.

3. The apparatus according to claim 1, wherein said second magnet is supported by a conductive member through which a coolant flows.

4. A deposition apparatus for forming a film on a deposition target, including a plasma generating apparatus according to claim 1.

5. A deposition method of forming a film on a deposition target using a deposition apparatus according to claim 4.

6. The method according to claim 5, wherein the film to be formed includes an MgO film.
